(19) United States
(12) Patent Application Publication
(10) Pub. No.: US 2013/0256884 A1
(43) Pub. Date: Oct. 3, 2013

(54) GRID FAN-OUT WAFER LEVEL PACKAGE AND METHODS OF MANUFACTURING A GRID FAN-OUT WAFER LEVEL PACKAGE

(71) Applicant: Thorsten Meyer, Regensburg (DE)

(72) Inventor: Thorsten Meyer, Regensburg (DE)

(73) Assignee: INTEL MOBILE COMMUNICATIONS GMBH, Neubiberg (DE)

(21) Appl. No.: 13/430,809

(22) Filed: Mar. 27, 2012

(51) Int. Cl. H01L 23/498; H01L 21/283

(52) U.S. Cl. 257/738; 257/786; 438/612; 257/E23.068; 257/E23.069; 257/E21.159

(57) ABSTRACT

In various aspects of the disclosure, a chip packaging arrangement may be provided. The chip packaging arrangement may include a dielectric layer with at least one semiconductor device adjoining the dielectric layer, at least one bonding area on the semiconductor device, the bonding area being exposed through the dielectric layer, a first material comprising a first coefficient of thermal expansion substantially surrounding the semiconductor device and adjoining the dielectric layer, a second material comprising a second coefficient of thermal expansion substantially surrounding the semiconductor device and the first material; and at least one conductive trace electrically connected to the semiconductor device.

### TECHNICAL FIELD

Various aspects of the disclosure relate generally to grid Fan-Out Wafer Level packages and to methods of manufacturing grid eWLB packages.

### BACKGROUND

Today, fabrication of integrated circuit devices usually includes packaging of the integrated circuits or semiconductor devices. In the fabrication of semiconductor device packages such as for example a laminate package or an Fan-Out Wafer Level Package such as embedded wafer level ball grid array (eWLB) it may be desirable to include a coefficient of thermal expansion (CTE) grid surrounding the semiconductor devices which is matched to the interconnect partners, e.g. a PCB board.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the disclosure of the invention are described with reference to the following drawings, in which:

FIG. 1 shows a chip packaging arrangement;

FIG. 2 shows a chip packaging arrangement in accordance with an aspect of the disclosure;

FIGS. 3A-F show diagrams illustrating a method of manufacturing a chip packaging arrangement in accordance with aspects of the disclosure;

FIGS. 4A-4D show diagrams illustrating a method of manufacturing a chip packaging arrangement in accordance with aspects of the disclosure;

FIG. 5 shows a chip packaging arrangement in accordance with another aspect of the disclosure;

FIG. 6 shows a chip packaging arrangement in accordance with another aspect of the disclosure.

FIG. 7 shows a manufacturing process in accordance with an aspect of the disclosure.

### DESCRIPTION

In various aspects of the disclosure, chip packaging arrangements may be provided that may include at least one semiconductor device, one or more bond pads, and an embedded grid. The embedded grid may be disposed to substantially surround the semiconductor device enclosed in the package. The embedded grid may be formed of a metal material. The embedded grid may be surrounded by a polymeric mold material. The package may be attached to a printed circuit board (PCB). The dimensions of the semiconductor device, embedded grid, and polymeric mold material may vary to provide a more reliable package/printed circuit board (PCB) structure. The embedded grid may compose substantially the same material as the underlying PCB. The embedded grid may have substantially the same coefficient of thermal expansion (CTE) as the underlying PCB.

The following detailed description refers to the accompanying drawings that show, by way of illustration, specific details and aspects of the disclosure in which the invention may be practiced. Other aspects of the disclosure may be utilized and structural, logical, and electrical changes may be made without departing from the scope of the invention. The various aspects of the disclosure are not necessarily mutually exclusive, as some aspects of the disclosure can be combined with one or more other aspects of the disclosure to form new aspects of the disclosure. The following detailed description therefore is not to be taken in a limiting sense, and the scope of the present invention is defined by the appended claims.

Various aspects of the disclosure are provided for devices, and various aspects of the disclosure are provided for methods. It will be understood that basic properties of the devices also hold for the methods and vice versa. Therefore, for sake of brevity, duplicate description of such properties may be omitted.

The terms “coupling” or “connection” as used herein may be understood to include a direct “coupling” or direct “connection” as well as an indirect “coupling” or indirect “connection”, respectively.

The terms “disposed over”, “located over” or “arranged over” as used herein are intended to include arrangements where a first element or layer may be disposed, located or arranged directly on a second element or layer with no further elements or layers in-between, as well as arrangements where a first element or layer may be disposed, located or arranged above a second element or layer with one or more additional elements or layers between the first element or layer and the second element or layer.

The expression “the grid surrounds” as used herein may be understood to indicate that an element or structure is located at least partially within the boundaries of a grid structure. For example, in accordance with some aspects of the disclosure where the grid is configured as a structure having one or more sides the term “surrounds” may be understood to indicate that an element or structure is enclosed by the one or more sides of the grid structure.

The term “thermal expansion rate” as used herein may be understood to the rate of change, in nm/° C., of the size of a structure with temperature. This is a quantity directly related to the coefficient of thermal expansion (CTE) of the material(s) used to form the structure

The term “bond pad” as used herein may be understood to include, for example, pads that will be contacted in a bonding process (for example, in a wire bonding process, in a flip chip process or in a ball attach process) of a die or chip. In case that a ball attach process is applied, the term “ball pad” may also be used.

The term “redistribution trace” as used herein may be understood to include, for example, conductive lines or traces disposed over a semiconductor device's or wafer's active surface and used to relocate a bond pad of the semiconductor device or wafer. In other words, a bond pad's original location over the semiconductor device or wafer may be shifted to a new location by means of a redistribution trace which may serve as an electrical connection between the (relocated) bond pad at the new location and an electrical contact (or pad) at the original location over the semiconductor device or wafer.

The term “redistribution layer (RDL)” as used herein may be understood to refer to a layer including at least one or more redistribution traces used to relocate (“redistribute”) a plurality of bond pads of a semiconductor device or wafer.

The term “reconstitution structure” as used herein may be understood to include, for example, a structure that may be formed (e.g. cast) around a semiconductor device to serve as an artificial wafer portion where, for example, additional bond pads may be placed (for example, in addition to bond pads located over the semiconductor device). Bond pads located over the reconstitution structure may be electrically connected to the semiconductor device (e.g. to electrical contacts or pads of the semiconductor device), for example, by means of redistribution traces of a redistribution layer. Thus, additional interconnects for a semiconductor device may be realized over the reconstitution structure (so-called “fan-out design”).

The term “embedded wafer level ball grid array (eWLB)” may be understood to refer to a Fan-out Wafer Level Package, a packaging technology for integrated circuits. In an eWLB package, interconnects may be applied on an artificial wafer made of semiconductor devices or chips (e.g. silicon semiconductor devices or chips) and a mold compound. Fan-Out Wafer Level Packages may be seen as a further development of the classical wafer level ball grid array technology (WLB or WLP: wafer level package). For example, all process steps for the generation of the package may be performed on the wafer. This may, for example, allow, in comparison to classical packaging technologies (e.g. ball grid array), the generation of very small and flat packages with improved electrical and thermal performance at decreased cost.

In WLB technologies, which are built on a wafer (e.g. silicon wafer), the interconnects (typically solder balls) usually fit on the chip (so-called fan-in design). Therefore, usually only chips with a restricted number of interconnects may be packaged since the pitch/distance between the interconnects (typically solder balls) cannot be reduced freely.

In contrast thereto, the Fan-Out Wafer Level Package technology may allow the realization of semiconductor devices or chips with a high number of interconnects. Here, the package may be realized not on a semiconductor wafer (e.g. silicon wafer) as for classical Wafer Level Package, but on an artificial wafer. To this end, a front-end-processed wafer (e.g. silicon wafer) may, for example, be diced and the singulated chips may be placed on a carrier. The distance between the chips may be chosen freely, but may be typically larger than on the silicon wafer. The gaps and the edges around the chips may be filled with a mold compound to form a wafer. After curing, an artificial wafer containing a mold frame around the semiconductor devices for carrying additional interconnect elements may be realized. After building the artificial wafer (the “reconstitution”) electrical connections from the semiconductor device or chipcontacts or pads to the interconnects may, for example, be realized in thin-film technology, like for other classical Wafer Level Package.

With Fan-Out Wafer Level Package technology an arbitrary number of additional interconnects may, in principle, be realized on the package in an arbitrary distance (so-called fan-out design). Therefore, the Fan-Out Wafer Level Package technology may, for example, also be used for space sensitive applications, where the area of the semiconductor device would not be sufficient to place the needed number of interconnects in a realizable or reasonable distance.

An eWLB may be seen as one example of a so-called fan-out wafer level package. In addition to eWLB, other types of fan-out wafer level packages are known, for example fan-out wafer level packages that are not mold compound-based or include so-called embedding technologies.

In the fabrication of packages such as for example a laminate package or a Fan-Out Wafer Level Packages (e.g. eWLB) a number of different materials must be used. The semiconductor device is often predominantly silicon, the reconstitution layer is often predominantly a polymeric mold compound, the redistribution layer is typically a metal or other conductor and the underlying printed circuit board (PCB) is a metal encased in a laminate polymer or other suitable material. Each of the aforementioned structures has associated with it a unique coefficient of thermal expansion (CTE), which is an inherent property of the material(s) used to form the structure(s). Due to the CTE associated with the various materials, the individual structures will expand or contract in size with variations in temperature. Because the CTEs for the various structures are different, the structures will move slightly relative to each other as the temperature of the local environment changes. In the application stage, with the package being mounted on a customer board for example, this causes stress in the interconnect elements due to the mismatch of CTEs between PCB board and package. Such movement can lead to, for instance, a failure of the packaged device. This is particularly problematic when the packaged device is subjected to thermal cycling. Moreover, the effect is magnified at the extremities of the package, such as at interconnect elements at the package edges, for instance. This is because the edges of the package experience the largest absolute mismatch in expansion.

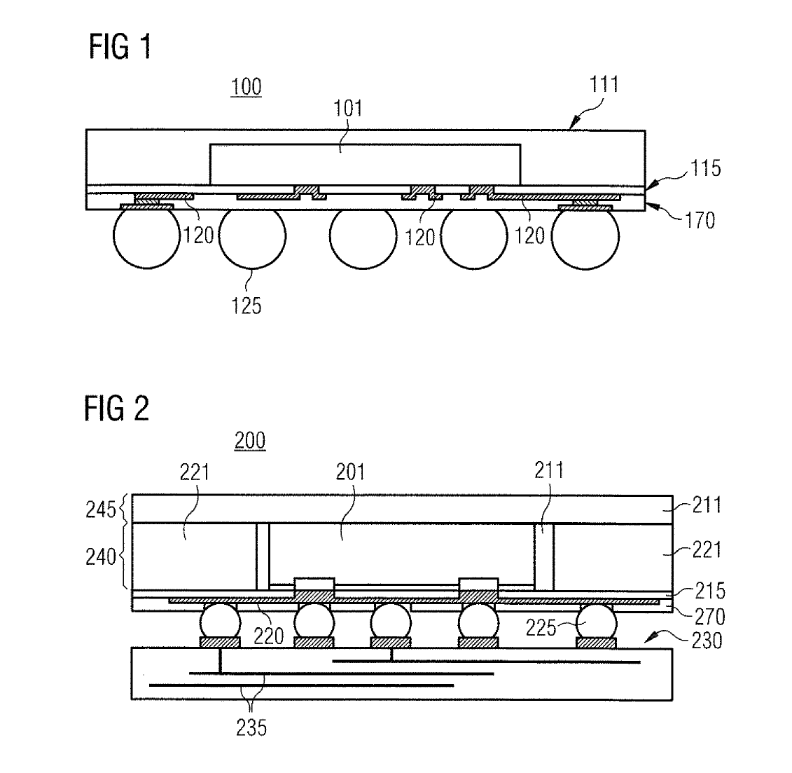

FIG. 1 shows a typical Fan-Out Wafer Level Package chip packaging arrangement 100 including a semiconductor device 101 and a reconstitution structure 111 surrounding semiconductor device 101. Reconstitution structure 111 is typically formed of a polymeric mold compound. The polymeric mold compound often is an epoxy-based compound. A dielectric layer 115 is disposed below reconstitution structure 111. The redistribution layer 120 is disposed below dielectric layer 115. A solder stop layer 170 is then disposed below the dielectric 115 and redistribution layers 120. Electrically attached to redistribution layer 120 are the solder balls 125. Solder balls 125 make an electrical connection to an underlying PCB (not shown). As discussed above, semiconductor device 100, reconstitution structure 111, redistribution layer 120 and PCB each will have a different CTE.

FIG. 2 shows an example of an eWLB in accordance with various aspects of the disclosure. FIG. 2 includes an eWLB chip packaging arrangement 200 including semiconductor device 201 and reconstitution structure 211 surrounding the semiconductor device 201. Reconstitution structure 211 is typically formed of a polymeric mold compound. Reconstitution structure 211 further includes an embedded grid 221. Grid 221 may compose any suitable material including, for example, copper or other metals or materials of appropriate CTE. Grid 221 is at least partially surrounded and enclosed by reconstitution structure 211. The shape of grid 221 will vary widely, depending on the specific package 200 design. Considerations that go into the shape and size of grid 221 will be discussed further below.

Underneath grid 221, semiconductor device 201, and reconstitution structure 211 is a partial layer of dielectric 215. Under dielectric layer 215 are the redistribution layers 220. Under the dielectric layer 215 and redistribution layers 220 is a partial solder stop layer 270. Attached to the redistribution layers 220 are solder balls 225 for electrically connecting package 200 to underlying PCB 230. In an example in accordance with various aspects of the disclosure, PCB 230 comprises one or more copper (Cu) metallization layers 235. Further in accordance with various aspects of the invention, grid 221 may also comprise Cu or stainless steel.

The effect of matching the material of grid 221 with that of metallization layers 235 of PCB 230 is that the effective CTEs for the two structures are substantially similar, or at least more similar than the CTEs of PCB 230, on the one hand, and that of reconstitution structure 211, on the other. Reducing the difference in the CTEs of these structures results in an decrease in the overall stress due to the total CTE difference of the various materials, when undergoing thermal cycling. Reduction in the overall stress typically results in an improvement in the reliability of the completed package/PCB structure. This is especially helpful in reducing stress on the interconnects at the package edge positions, as the mismatch in expansion is minimized, to the extent possible.

However, the CTE-matching between package 200 and PCB 230 cannot be exact. This is because the CTE difference between silicon semiconductor device 200, which is contained within the package 200, and package 200 must not be too great, or warpage of the package may occur, for instance. Therefore, in a second aspect of the invention, the dimensions of the various components comprising first layer 240 incorporating semiconductor device 201 are chosen so as to minimize the difference between the effective thermal expansion rate of semiconductor device-containing layer 240 of the package and topmost layer of the package 245, which is substantially disposed with mold compound. Dimensional calculations are done using known methods. Methods for manufacturing a package 200 according to various aspects of the disclosure will be discussed below.

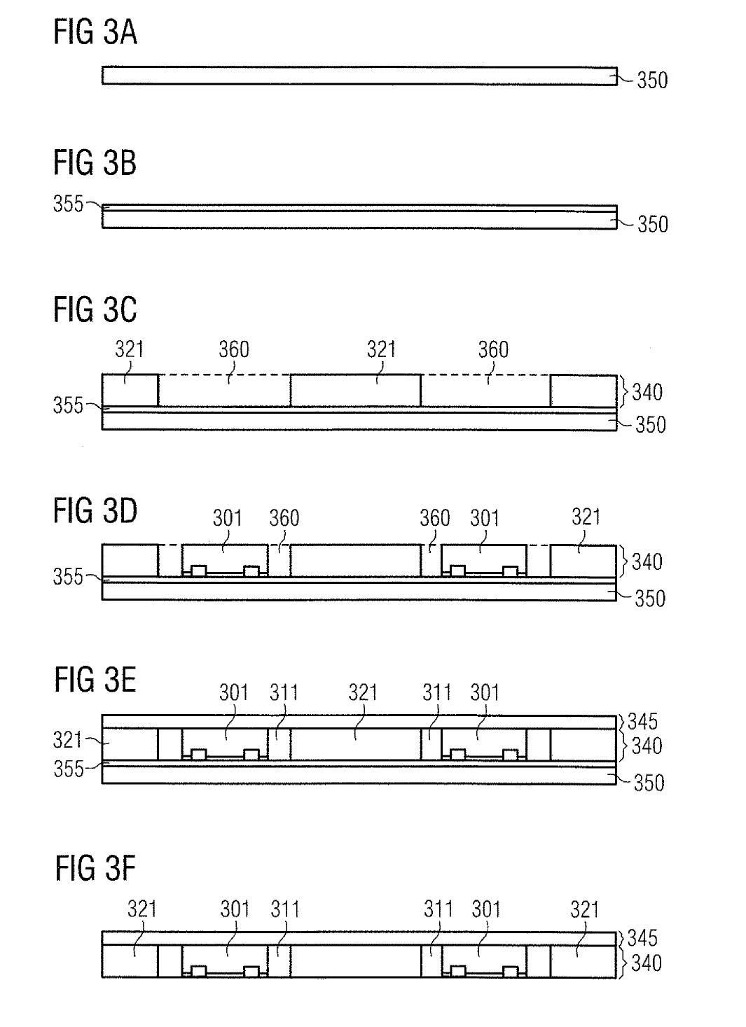

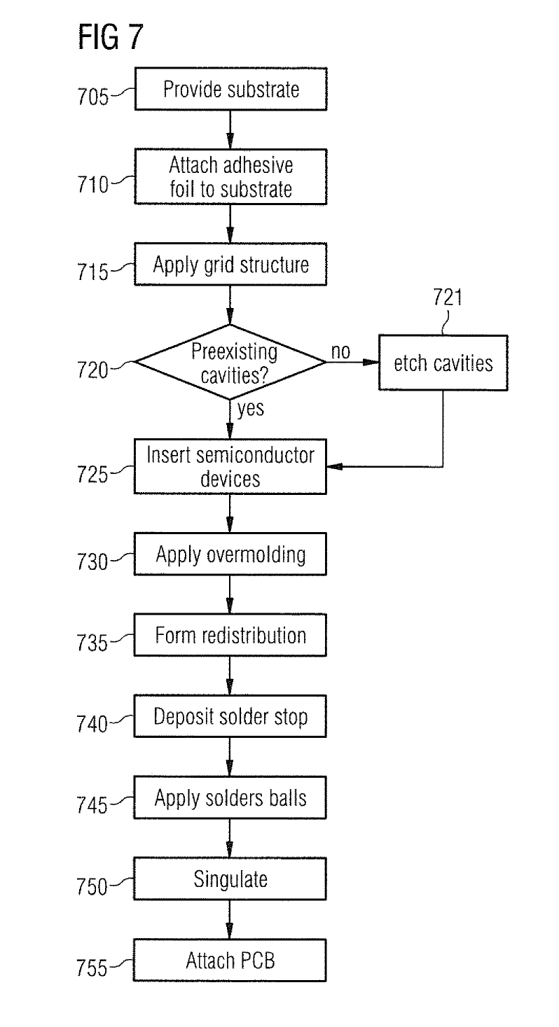

In FIGS. 3A-3H, and 7 a manufacturing process for producing a package in accordance with various aspects of the disclosure is illustrated.

In FIG. 3A and at 705 of FIG. 7, substrate 350 that will act as a carrier 350 for the package during the build-up process is provided. Carrier 350 may be any material with suitable strength, hardness, and durability for the purpose. Examples include, but are not limited to, metal, silicon, polymer, sapphire or ceramic materials. In an embodiment according to an aspect of the disclosure, metal is used.

In FIG. 3B and at 710 of FIG. 7, adhesive foil 355 is laminated onto substrate 350. In an aspect of the of the disclosure, adhesive foil 355 is a releasable foil. In a further aspect, the adhesive foil 355 may comprise an energy or chemical-releasable material. The energy source used to affect release may be heat, for example. However, the type and thickness of adhesive foil 355 used is not critical for the purposes of this disclosure.

In FIG. 3C and at 715 of FIG. 7, grid 321 structure is applied to adhesive foil 355. In an aspect of the disclosure, grid 321 structure may be supplied as a preformed piece, such as is illustrated in FIGS. 5 and 720 of FIG. 7. When grid 321 structure is supplied as a preformed piece, it can be applied directly to adhesive foil 355 with little or no additional processing necessary to further form grid 321 structure. This may advantageously reduce the number of steps in the package manufacturing process, for instance. A preformed grid 321 structure can be supplied in a number of thicknesses, in accordance with various aspects of the disclosure. The thickness of grid 321 structure will vary widely depending on the specific package and the engineering requirements. The size of cavities 360 within or between the grid structure 321 will also vary depending on various requirements, as discussed further below.

A primary purpose of grid 321 structure is to enable the package designer to better adapt the thermal expansion rate of the package to that of the underlying PCB. Therefore, the CTE of grid 321 structure is of primary interest. As a result, the choice of material for grid 321 structure will depend primarily on the desired CTE, which is a CTE which is substantially matching the CTE of the PCB, ceramics, Flex or other board material the package is attached to by connection with the solder balls. A metal such as copper will often represent a good choice because copper is often used in the construction of printed circuit boards. However, the current method is not limited to copper-based grid 321 structures, or even to metal grid 321 structures. The grid 321 structure may comprise any material having the desired CTE, including, but not limited to, metals or metal alloys (such as stainless steel), polymers, ceramics, or any other material of suitable CTE.

In an aspect of the disclosure, the thickness of grid 321 structure will vary depending on a number of factors, including, but not limited to, the thickness of the semiconductor device 301. In general, the degree of warpage due to CTE mismatch becomes less as the thickness of grid 321 structure increases. Therefore, in an aspect of the disclosure, the thickness of grid 321 structure will be greater than that of semiconductor device 301. However, in a further aspect of the disclosure, the thickness of grid 321 structure is substantially equal to the thickness of semiconductor device 301.

In yet a further aspect of the disclosure, the thickness of grid 321 structure is less than the thickness of semiconductor device 301. There may be certain process-related advantages to this aspect of the disclosure, for instance. In one aspect, forming the thickness of grid 321 structure less than the thickness of semiconductor device 301 may allow for easier molding in subsequent overmolding steps, for example.

In yet another aspect of the disclosure, a plurality of layers are used to form grid 321 structure. The plurality of layers may be formed using any suitable process, including any of the processes illustrated above. Additionally, the plurality of layers may be formed of one or more materials, depending on the packaging requirements and the effective thermal expansion rate desired for the package.

In a another aspect of the disclosure, grid 321 structure may first be applied to adhesive foil 355 as one or more solid pieces. This may provide certain advantages with respect to processing, for instance. In accordance with this aspect of the disclosure, cavities 360 must be created in grid 321 structure once it has been applied to adhesive foil 355 carrier. Therefore, in a subsequent step, cavities 360 may be etched into grid 321 structure using any process compatible with the materials used for grid 321 structure, adhesive foil 355, and substrate 350. Etching may take the form of chemical etching, dry etch, or lasing etching, for instance. In an aspect of the disclosure, prior to etching a resist layer is deposited. The resist may be any suitable material. In an aspect of the disclosure, the resist comprises a polymeric material. Following deposition and (if necessary) cure of the resist, it is patterned using methods appropriate for the resist material. The specific resist deposition and patterning processes used herein are dependent on grid 321 structure used.

As illustrated by 721 of FIG. 7, following patterning of the resist, the exposed pattern is etched. In an aspect of the disclosure, a wet etch process is used. Suitable wet etch processes will depend on grid 321 structure material used, and the instant disclosure is not dependent on the type of wet etch process. In another aspect of the disclosure, a dry etch process is used. Similarly, the dry etch process will depend primarily on the material used to form grid 321 structure, and as a result, any number of dry etch processes will be suitable for the purposes of this disclosure.

In FIGS. 3D and 725 of FIG. 7, following patterning (if necessary), one or more semiconductor devices 301 are applied into cavities 360 of grid 321 structure and attached to underlying adhesive foil 355. In an aspect of the disclosure, a pick and place process is used to dispose semiconductor device 301. In another aspect of the disclosure, semiconductor devices 301 which have been previously tested on the front end of the process as good are used, to maximize yield of the packaged devices. Semiconductor devices 301 are placed active (or circuit) side-down, so that the contacts are facing the bottom of the package and are available to the metal redistribution lines 320 below. In an aspect of the disclosure, semiconductor device 301 may comprise a dielectric layer covering the active circuitry and in-between the circuitry and the adhesive foil 355. In another aspect of the disclosure, semiconductor device 301 may comprise copper metallization on the chip pads.

In FIGS. 3E and 730 of FIG. 7, the overmolding process is illustrated. This process disposes a standard polymeric mold compound over the grid 321, semiconductor device 301, and cavities 360. In an aspect of the disclosure, polymeric mold compound is an epoxy compound.

In FIG. 3E, semiconductor device 301 and grid 321 structure are embedded into the mold compound. Typically, gaps between semiconductor device 301 and grid 321 structure must also be filled in with mold compound. In an aspect of the disclosure, the thickness of mold compound over first layer 340 containing semiconductor device 301 is minimized. The mold compound is then cured. Following curing, adhesive foil 355 and carrier 350 are removed from the artificial wafer thus formed e.g. by the addition of energy, as shown in FIG. 3F.

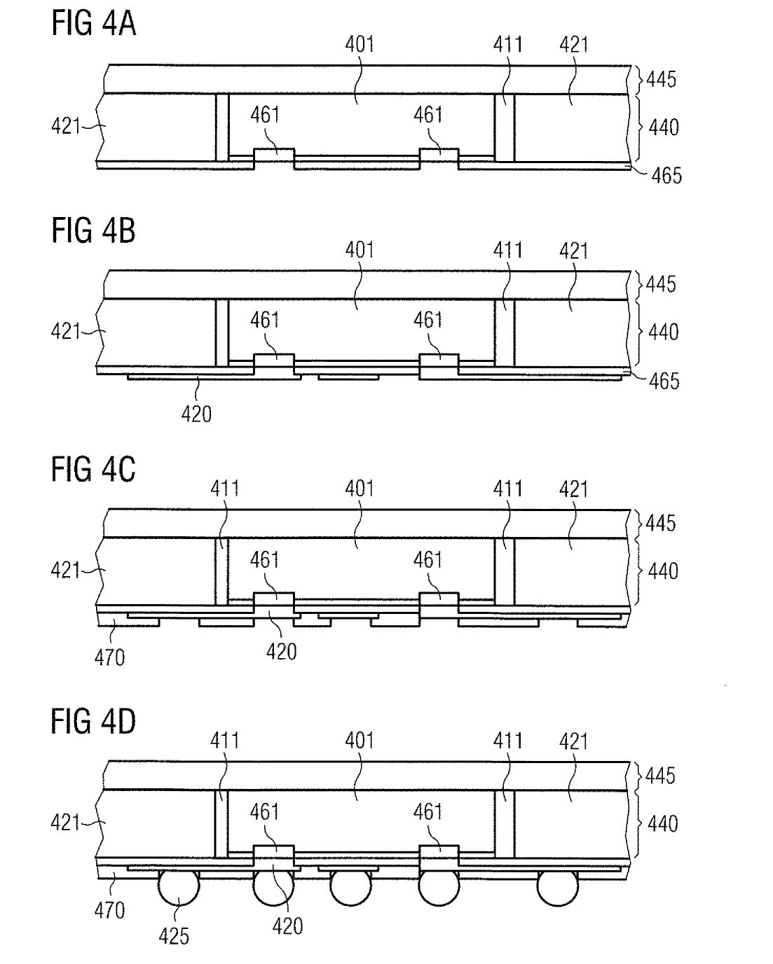

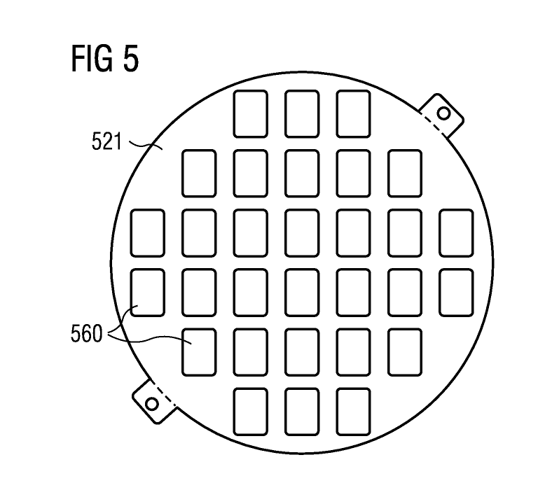

FIGS. 4A, 4B and 735 of FIG. 7B illustrate the formation of the redistribution layers. In FIG. 4A, a partial dielectric layer 465 is deposited on the lower side of the reconstituted wafer. This layer is deposited using any method which is compatible with the layers previously deposited on the Fan-Out Wafer Level Package including, but not limited to, spin-coating, lamination, or printing, for example. The grid Fan-Out Wafer Level Package disclosed in this aspect of the invention compatible with a wide variety of dielectric 465 deposition methods, and as such, this aspect of the invention is not limited by the method employed. The dielectric layer 465 is a partial layer because it must, for example, leave contacts 461 to semiconductor device 401 exposed to enable electrical connections to be formed to an underlying PCB.

In FIGS. 4B and 735 of FIG. 7, the redistribution traces 420 are deposited, and electrically connected to electrical contacts, using known deposition methods. As the currently-disclosed grid Fan-Out Wafer Level Package is not dependent on the method used to apply redistribution traces 420, the specific details of the processes of the various methods will not be discussed.

In one aspect of the embodiment, redistribution traces 420 can be applied using thin film deposition techniques. Such techniques include the steps of 1) depositing a metal layer, either through sputtering or chemical vapor deposition; 2) forming a photoresist layer; 3) patterning the photoresist layer using a mask and though exposure to an appropriate light source; 4) removing the non-patterned resist, using for example, wet chemical techniques or dry etch techniques; 5) removing the metal film from areas not covered by photoresist using wet chemical or dry etch techniques; 6) removing the remaining photoresist using wet chemical or dry etch techniques.

In a second aspect of the disclosure, redistribution traces 420 can be applied using plating techniques. Such techniques include the steps of 1) depositing a plating mask; 2) patterning the plating mask; 3) plating the metal traces onto the substrate using standard electroplating or electroless plating techniques; 4) removing the plating mask using wet chemical or other methods; 5) removing the metal film from areas not covered by photoresist using wet chemical or dry etch techniques.

Following application of conductive redistribution traces 420, a solder stop 470 is applied over redistribution traces 420 as illustrated in FIGS. 4C and 740 of FIG. 7. This is done to prevent application of solder to areas where it might not be desirable, such as in areas where it might bridge conductors, for instance. Solder stop 470 can be applied through a number of methods including, but not limited to, spin-coating of epoxy based, polyimide based or any other polymer based liquid, dry film lamination, or printing of liquid photoimageable or not photoimageable solder stop. Following deposition and patterning to expose electrical contacts 467, solder stop 470 may be subjected to a thermal cure, if required.

In an aspect of the disclosure, solder balls 425 are next placed onto the exposed electrical contacts 461 using automated equipment.

Following deposition and curing of solder stop 470, the packages are singulated, as illustrated at 750 in FIG. 7. This is done using methods known in the industry. In an aspect of the disclosure, semiconductor devices 401 in the artificial wafer are singulated using wafer sawing techniques.

Next, singulated semiconductor components are placed onto a PCB, as illustrated at 755 in FIG. 7. Following placement of components onto the PCB, solder paste which was printed on the PCB board prior to placement of the package the entire assembly is heated using, for instance, a reflow oven. This causes the solder to melt and to reflow. Following reflow, the part is allowed to cool so that the solder solidifies. This forms a structure as illustrated in FIG. 2, for instance.

In another aspect of the disclosure, the components are attached to the PCB using other known methods. Other methods include, but are not limited to, solder bumps, land grid array (LGA), column grid array (CGA) or other BGA alternatives. The methods described herein are not limited by the method of PCB attachment used, and as such, the above description is merely exemplary.

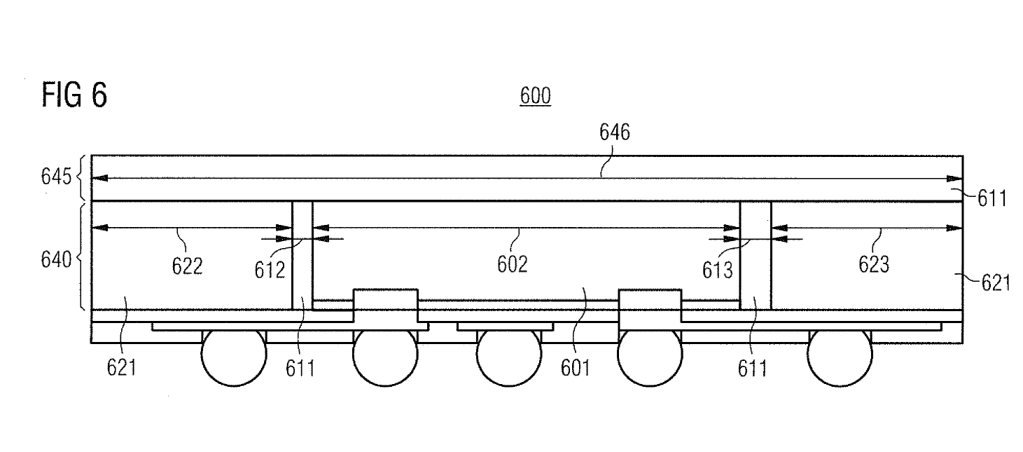

FIG. 6 illustrates an exemplary semiconductor package in accordance with an aspect of the disclosure. FIG. 6 includes an Fan-Out Wafer Level Package 600. Package 600 includes first layer 640 and second layer 645. First layer 640 includes copper grid 621 structure, mold compound 611, and semiconductor device 601. Grid 621 structure has target widths 622 and 623 with a value such as a mm, mold compound has target widths 612 and 613 with a value such as b mm, and semiconductor device 601 has (known) width 602 of 5 mm, for example. Second layer 645, which comprises mold compound, has width 646=8 mm, for example. The coefficients of thermal expansion for the various components are: grid 621 structure, 16 ppm/° C.; mold compound 611, 7 ppm/° C.; and semiconductor device 601, 3 ppm/° C.

A target expansion rate calculation according to an aspect of the current disclosure yielded the following results:

Second layer 645 expansion rate=width*CTE=(8 mm)(7 ppm)=0.056 nm/° C.

To minimize potential for package warping, a dimensional calculation is done to match effective expansion rate for first layer to expansion rate for second layer: (2)(a mm)(16 ppm)+(2)(c mm)(7 ppm)+(5 mm)(3 ppm)=Rate (nm/° C.).

Solving for variables a, b, and c using known methods, the component target widths are as follows: grid 621 structure has widths 622 and 623 with a value of 1.2 mm, mold compound has widths 612 and 613 with a value of 0.3 mm, and semiconductor device 601 has width 602 with a value of 5 mm, with a target expansion rate of 0.0576 nm/° C., for example. Through such target thicknesses, a grid eWLB package in accordance with several aspects of the disclosure may be realized.

A person skilled in the art will recognize that combinations of the above exemplary embodiments may be formed. For example, in some aspects of the disclosure it may not be necessary to form a second layer of mold compound over the grid-containing layer. In this case, the relative sizes of the constituents in the grid-containing layer may be less important. Moreover, the use of certain grid materials may render the use of mold compound in the grid-containing layer unnecessary, for instance. Similarly, the use of two or more different mold compounds or two or more grid layers falls within the scope of this disclosure.

While the invention has been particularly shown and described with reference to specific aspects of the disclosure, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A chip packaging arrangement, comprising:
a dielectric layer;
at least one semiconductor device adjoining the dielectric layer;
at least one bonding area on the at least one semiconductor device, the bonding area being exposed through the dielectric layer;
a first material comprising a first coefficient of thermal expansion substantially surrounding the at least one semiconductor device and adjoining the dielectric layer and;
a second material comprising a second coefficient of thermal expansion substantially surrounding the at least one semiconductor device and the first material.

2. The chip packaging arrangement of claim 1, wherein the package is further connected to a printed circuit board (PCB).

3. The chip packaging arrangement of claim 1, wherein the first coefficient of thermal expansion is greater than the second coefficient of thermal expansion.

4. The chip packaging arrangement of claim 1, wherein the first material is a metal.

5. The chip packaging arrangement of claim 1, wherein the first material is copper.

6. The chip packaging arrangement of claim 2, wherein the coefficient of thermal expansion of the PCB is substantially similar to the coefficient of thermal expansion of the first material.

7. The chip packaging arrangement of claim 1, wherein the second material comprises a mold compound.

8. A method of manufacturing a chip packaging arrangement, the method comprising:
providing at least one semiconductor device;
forming at least one contact on the at least one semiconductor device;
surrounding the at least one semiconductor device with a first material comprising a first coefficient of thermal expansion;
forming a first layer by surrounding the first material and the at least one semiconductor device with a second material comprising a second coefficient of thermal expansion;
forming a partial layer of dielectric adjoining the first material and the at least one semiconductor device.

9. The method of manufacturing a chip packaging arrangement of claim 8, further comprising forming a second layer adjacent the first layer, the second layer comprising the second material comprising a second coefficient of thermal expansion.

10. The method of manufacturing a chip packaging arrangement of claim 8, further comprising forming a partial solder stop layer adjoining the partial layer of dielectric.

11. A chip packaging arrangement, comprising:
at least one semiconductor device comprising an electrical contact;
a first material comprising a first coefficient of thermal expansion adjoining a dielectric material and at least partially surrounding the semiconductor device;
a second material comprising a second coefficient of thermal expansion at least partially surrounding the semiconductor device and the first material.

12. The chip packaging arrangement of claim 23, wherein the redistribution trace is further connected to a printed circuit board via electrical connection means.

13. The chip packaging arrangement of claim 12, wherein said electrical connection means comprise solder.

14. The chip packaging arrangement of claim 13, wherein said electrical connection means further comprise solder balls.

15. The chip packaging arrangement of claim 11, configured as an embedded wafer level ball grid array.

16. A chip packaging arrangement, comprising:
a first layer comprising a semiconductor device having an electrical contact, the semiconductor device comprising a first coefficient of thermal expansion;
a first material comprising a second coefficient of thermal expansion adjoining a dielectric material and at least partially surrounding the semiconductor device in the first layer;
a second material comprising a third coefficient of thermal expansion at least partially surrounding the semiconductor device and the first material in the first layer;
a second layer comprising the second material adjoining the first layer.

17. The chip packaging arrangement of claim 16, wherein the dimensions of the semiconductor device, first material and second material are chosen wherein the first layer has an effective rate of thermal expansion compatible with the rate of thermal expansion of the second layer.

18. The chip packaging arrangement of claim 16, wherein the redistribution trace is further connected to a printed circuit board.

19. The chip packaging arrangement of claim 16, wherein the second material comprises a mold compound.

20. A device, comprising:
a first layer comprising a semiconductor device comprising an electrical contact, the semiconductor device comprising a first coefficient of thermal expansion;
a first material comprising a second coefficient of thermal expansion adjoining a dielectric material and at least partially surrounding the semiconductor device in the first layer;
a second material comprising a third coefficient of thermal expansion at least partially surrounding the semiconductor device and the first material in the first layer;
a second layer comprising the second material adjoining the first layer.

21. The chip packaging arrangement of claim 1, wherein at least one conductive trace is electrically connected to the at least one semiconductor device.

22. The method of manufacturing a chip packaging arrangement of claim 8, further comprising forming an electrical connection to the bond pad.

23. The chip packaging arrangement of claim 11, further comprising a redistribution trace connect with the electrical contact.

24. The chip packaging arrangement of claim 16, further comprising a redistribution trace connected to the electrical contact.

25. The device of claim 20, further comprising a redistribution trace connected to the electrical contact.
